(19) United States
(12) Patent Application Publication
(10) Pub. No.: US 2014/0285273 A1
(43) Pub. Date: Sep. 25, 2014

(54) SEMICONDUCTOR DEVICE

(71) Applicant: KABUSHIKI KAISHA TOSHIBA, Tokyo (JP)

(72) Inventor: Mitsuyoshi ENDO, Kanagawa (JP)

(21) Appl. No.: 13/939,083

(22) Filed: Jul. 10, 2013

(30) Foreign Application Priority Data
Mar. 22, 2013 (JP) 2013-060296

(51) Int. Cl. H03B 1/00

(52) U.S. Cl. CPC H03B 1/00
USPC 331/117 R

(57) ABSTRACT

According to one embodiment, there is provided a semiconductor device including a first capacitance electrode, a second capacitance electrode, and a depletion layer. The first capacitance electrode is buried in a hole via an insulating film. The hole is formed in a semiconductor substrate. The second capacitance electrode is formed on a front surface side or on a back surface side of the semiconductor substrate so as to be separated from the first capacitance electrode. The depletion layer forming mechanism includes a control electrode, and forms a depletion layer between the first capacitance electrode and the second capacitance electrode.

### CROSS-REFERENCE TO RELATED APPLICATIONS

This application is based upon and claims the benefit of priority from Japanese Patent Application No. 2013-060296, filed on Mar. 22, 2013; the entire contents of which are incorporated herein by reference.

### FIELD

Embodiments described herein relate generally to a semiconductor device.

### BACKGROUND

A semiconductor device including an LC resonance circuit may use a variable capacitance element for controlling a resonance point of the LC resonance circuit. A capacitance value of the variable capacitance element is desired to be large in order to secure a wide control range of the resonance point. In addition, it is desired that the size of the variable capacitance element is small in order to realize compact mounting of the semiconductor device.

### BRIEF DESCRIPTION OF THE DRAWINGS

FIG. 1 is a view illustrating a schematic configuration of a semiconductor device according to a first embodiment;

FIG. 2 is a diagram illustrating a variable capacitance element and a control circuit according to the first embodiment;

FIG. 3 is a view illustrating a cross-sectional structure of the variable capacitance element according to the first embodiment;

FIG. 4 is a view illustrating an operation of the variable capacitance element according to the first embodiment;

FIG. 5 is a view illustrating a cross-sectional structure of the variable capacitance element according to the first embodiment;

FIG. 6 is a view illustrating a cross-sectional structure of a variable capacitance element according to a second embodiment;

FIG. 7 is a view illustrating a cross-sectional structure of a variable capacitance element according to a modification of the first embodiment and the second embodiment;

FIG. 8 is a view illustrating a cross-sectional structure of a variable capacitance element according to a modification of the first embodiment and the second embodiment;

FIG. 9 is a view illustrating a cross-sectional structure of a variable capacitance element according to a modification of the first embodiment and the second embodiment;

FIG. 10 is a view illustrating a cross-sectional structure of a variable capacitance element according to a modification of the first embodiment and the second embodiment;

FIG. 11 is a view illustrating a structure of a variable capacitance element according to a comparative example; and

FIG. 12 is a view illustrating a structure of a variable capacitance element according to another comparative example.

### DETAILED DESCRIPTION

In general, according to one embodiment, there is provided a semiconductor device including a first capacitance electrode, a second capacitance electrode, and a depletion layer. The first capacitance electrode is buried in a hole via an insulating film. The hole is formed in a semiconductor substrate. The second capacitance electrode is formed on a front surface side or on a back surface side of the semiconductor substrate so as to be separated from the first capacitance electrode. The depletion layer forming mechanism includes a control electrode, and forms a depletion layer between the first capacitance electrode and the second capacitance electrode.

Exemplary embodiments of a semiconductor device will be explained below in detail with reference to the accompanying drawings. The present invention is not limited to the following embodiments.

### First Embodiment

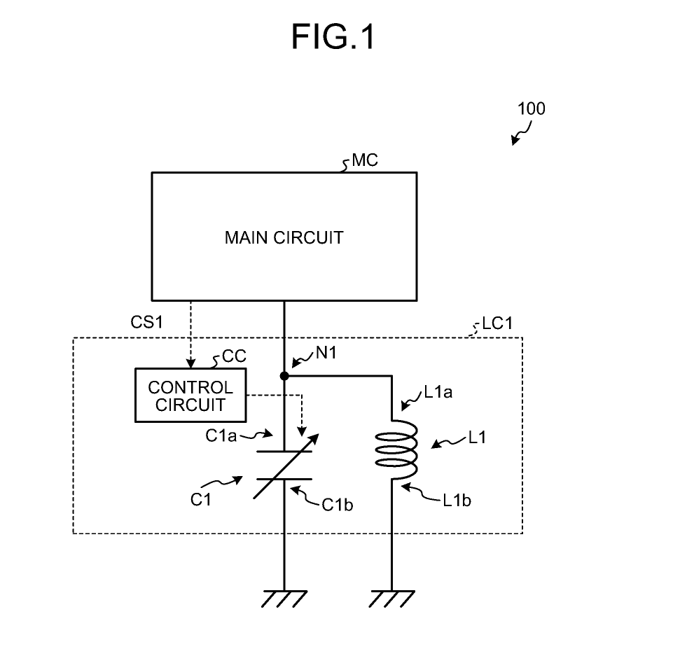

A semiconductor device 100 according to a first embodiment will be described with reference to FIG. 1. FIG. 1 is a view illustrating a schematic configuration of the semiconductor device 100.

The semiconductor device 100 includes an LC resonance circuit LC1, and a main circuit MC, for example. The LC resonance circuit LC1 includes a variable capacitance element C1, a control circuit CC, and an inductance element L1.

The variable capacitance element C1 and the inductance element L1 are connected in parallel between the main circuit MC and a ground potential, for example. One end C1a of the variable capacitance element C1 is connected to the main circuit MC and the inductance element L1 via a connection node N1, while the other end C1b is connected to the ground potential, for example. One end L1a of the inductance element L1 is connected to the main circuit MC and the variable capacitance element C1 via the connection node N1, while the other end L1b is connected to the ground potential, for example.

The control circuit CC receives a control signal CS1 from the main circuit MC to control the variable capacitance element C1 according to the control signal CS1. For example, the control circuit CC controls the variable capacitance element C1 in order that the capacitance of the variable capacitance element C1 becomes close to a target value represented by the control signal CS1. Thus, it is controlled such that the resonance frequency of the LC resonance circuit LC1 becomes close to a value according to the target value of the capacitance of the variable capacitance element C1.

The main circuit MC controls a resonance point (resonance frequency) of the LC resonance circuit LC1, and carries out operation using the resonance point of the LC resonance circuit LC1. For example, the main circuit MC is a communication circuit, and carries out an impedance matching between an antenna and a filter by using the resonance point of the LC resonance circuit LC1. Alternatively, the main circuit MC is a transmitting circuit for adjusting a frequency of a transmitting signal by using the resonance point of the LC resonance circuit LC1. Alternatively, the main circuit MC is a receiving circuit for adjusting a frequency of a receiving signal by using the resonance point of the LC resonance circuit LC1. For example, the main circuit MC may be other circuits that can utilize the variation in the resonance point of the LC resonance circuit LC1.

In order to secure a wide control range of the resonance point in the LC resonance circuit LC1, it is desirable that the capacitance value of the variable capacitance element C1 is large. In order to realize compact mounting of the semiconductor device 100 including the LC resonance circuit LC1, it is desirable that the size of the variable capacitance element C1 is small.

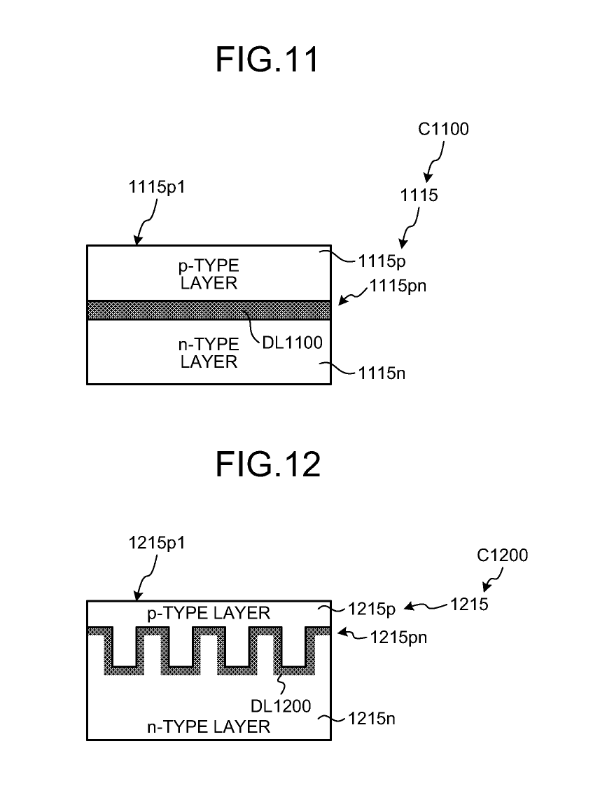

Suppose a case where a variable capacitance element C1100 illustrated in FIG. 11 is used as the variable capacitance element in the LC resonance circuit LC1. In the variable capacitance element C1100, a capacitance terminal 1140 is connected to a p-type layer 1115p of a semiconductor layer 1115 and one end 1130a of a voltage generating circuit 1130, and a capacitance terminal 1150 is connected to an n-type layer 1115n of the semiconductor layer 1115 and the other end 1130b of the voltage generating circuit 1130. The voltage generating circuit 1130 varies a value of a reverse bias voltage applied between the p-type layer 1115p and the n-type layer 1115n (between the capacitance terminal 1140 and the capacitance terminal 1150) according to the control signal CS1 (see FIG. 1), thereby increasing and decreasing the length of a depletion layer DL1100 in a pn junction 1115pn from the p-type layer 1115p toward the n-type layer 1115n. Thus, the capacitance value of the variable capacitance element C1100 between the capacitance terminal 1140 and the capacitance terminal 1150 is changed.

However, since the capacitance value is mainly determined according to the pn junction area in the variable capacitance element C1100 illustrated in FIG. 11, an electrode area has to be increased in order to increase the capacitance value. When the electrode area is increased, the size of the variable capacitance element C1100 in the direction along a surface 1115p1 might become large. This might increase a chip area of the semiconductor device 100 including the variable capacitance element C1100, for example, so that it becomes difficult to realize compact mounting of the semiconductor device 100.

To avoid this situation, suppose a case in which a variable capacitance element C1200 illustrated in FIG. 12 is used as the variable capacitance element in the LC resonance circuit LC1. As illustrated in FIG. 12, a pn junction 1215pn between a p-type layer 1215p and an n-type layer 1215n of the semiconductor layer 1215 has a trench structure. According to this structure, the capacitance value of the variable capacitance element C1200 can be increased, while suppressing the increase in the size of the variable capacitance element C1200 along a surface 1215p1.

However, even in the variable capacitance element C1200 illustrated in FIG. 12, the capacitance value is mainly determined according to the area of the pn junction, so that the depth of each trench has to be set large, or the pitch between the trenches has to be set small, in order to increase the capacitance value. Since the variable capacitance element C1200 illustrated in FIG. 12 has a limitation in the precision of ion implantation, it is difficult to deepen each trench in consideration of a process. When the pitch between trenches is set to be small in the variable capacitance element C1200 in FIG. 12, the depletion layer might be combined between the adjacent trenches, and hence, the effective electrode area might be decreased. Therefore, slight increase in the capacitance value is only realized in the variable capacitance element C1200 illustrated in FIG. 12. Thus, it is difficult to increase the capacitance in the variable capacitance element C1200 in FIG. 12.

In view of this, in the present embodiment, some efforts described below are made in order to secure a large capacitance value of the variable capacitance element C1 and to reduce the size of the variable capacitance element C1.

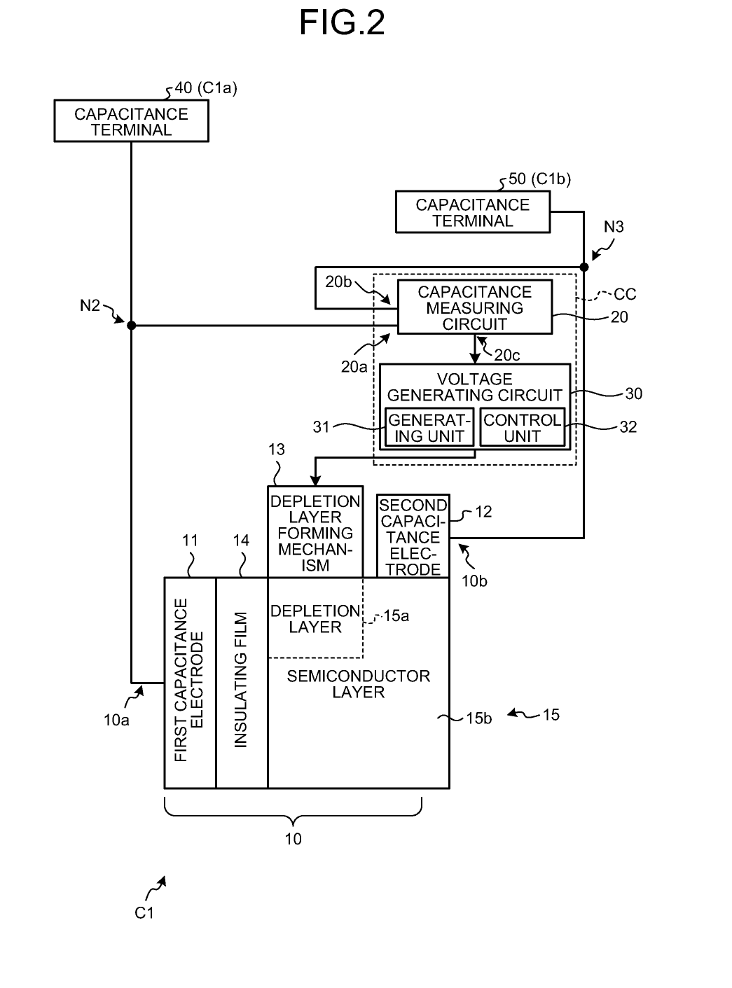

Specifically, the variable capacitance element C1 and the control circuit CC are configured to be those illustrated in FIG. 2. FIG. 2 is a diagram illustrating the structure of the variable capacitance element C1 and the control circuit CC.

The variable capacitance element C1 varies the capacitance of the variable capacitance element C1 under the control of the control circuit CC. For example, the variable capacitance element C1 includes a body 10, a capacitance terminal 40, and a capacitance terminal 50. The body 10 includes a first capacitance electrode 11, a second capacitance electrode 12, an insulating film 14, a semiconductor layer 15, and a depletion layer forming mechanism 13.

The capacitance terminal 40 functions as one end C1a (see FIG. 1) of the variable capacitance element C1, for example. Specifically, the capacitance terminal 40 is provided for extracting the capacitance value of the variable capacitance element C1 to the outside (e.g., the main circuit MC in FIG. 1). The capacitance terminal 40 is electrically connected to one end 10a of the body 10. For example, the capacitance terminal 40 is connected to the first capacitance electrode 11.

The capacitance terminal 50 functions as the other end C1b (see FIG. 1) of the variable capacitance element C1, for example. Specifically, the capacitance terminal 50 is provided for extracting the capacitance value of the variable capacitance element C1 to the outside (e.g., the main circuit MC in FIG. 1). The capacitance terminal 50 is electrically connected to the other end 10b of the body 10. For example, the capacitance terminal 50 is connected to the second capacitance electrode 12.

The first capacitance electrode 11 is provided close to one end 10a of the body 10, and functions as an electrode on one end 10a of the variable capacitance element C1. Specifically, the first capacitance electrode 11 is provided on the side reverse to the second capacitance electrode 12 across the insulating film 14 and the semiconductor layer 15. The first capacitance electrode 11 may be made of a conductor, and may be made of tungsten or copper, for example. Alternatively, it may be made of semiconductor having conductivity, such as polysilicon containing an impurity (e.g., boron, aluminum, etc.) of a first conductive type (e.g., p-type), or polysilicon containing an impurity (e.g., phosphor, arsenic, etc.) of a second conductive type (e.g., n-type). The second conductive type is reverse to the first conductive type.

The second capacitance electrode 12 is provided close to the other end 10b of the body 10, and functions as an electrode on the other end 10b of the variable capacitance element C1. Specifically, the second capacitance electrode 12 is provided on the side reverse to the first capacitance electrode 11 across the insulating film 14 and the semiconductor layer 15. The second capacitance electrode 12 may be made of a conductor, and may be made of tungsten or copper, for example. Alternatively, it may be made of semiconductor having conductivity, such as polysilicon containing an impurity (e.g., boron, aluminum, etc.) of a first conductive type (e.g., p-type), or polysilicon containing an impurity (e.g., phosphor, arsenic, etc.) of a second conductive type (e.g., n-type).

The insulating film 14 is provided between the first capacitance electrode 11 and the second capacitance electrode 12 to form a part of an electric capacitance between the first capacitance electrode 11 and the second capacitance electrode 12. The insulating film 14 is provided between the first capacitance electrode 11 and the semiconductor layer 15 so as to electrically insulate the first capacitance electrode 11 and the semiconductor layer 15, for example. The insulating film 14 may be made of a material containing silicon oxide as a main component, or may be made of a material containing silicon nitride as a main component.

The semiconductor layer 15 is provided between the first capacitance electrode 11 and the second capacitance electrode 12 to form a part of the remaining electric capacitance between the first capacitance electrode 11 and the second capacitance electrode 12. The semiconductor layer 15 is provided between the insulating film 14 and the second capacitance electrode 12, for example. In the semiconductor layer 15, a depletion layer 15a is formed in a region between the first capacitance electrode 11 and the second capacitance electrode 12, e.g., in a region between the insulating film 14 and the second capacitance electrode 12, by the depletion layer forming mechanism 13. Since the depletion layer 15a equivalently functions as an insulator, the semiconductor layer 15 can form a part of the remaining electric capacitance between the first capacitance electrode 11 and the second capacitance electrode 12.

It should be noted that the semiconductor layer 15 may be made of semiconductor containing an impurity (e.g., boron, aluminum, etc.) of a first conductive type (e.g., p-type), or semiconductor containing an impurity (e.g., phosphor, arsenic, etc.) of a second conductive type (e.g., n-type). This structure can allow a region 15b other than the depletion layer 15a in the semiconductor layer 15 not to equivalently function as an insulator.

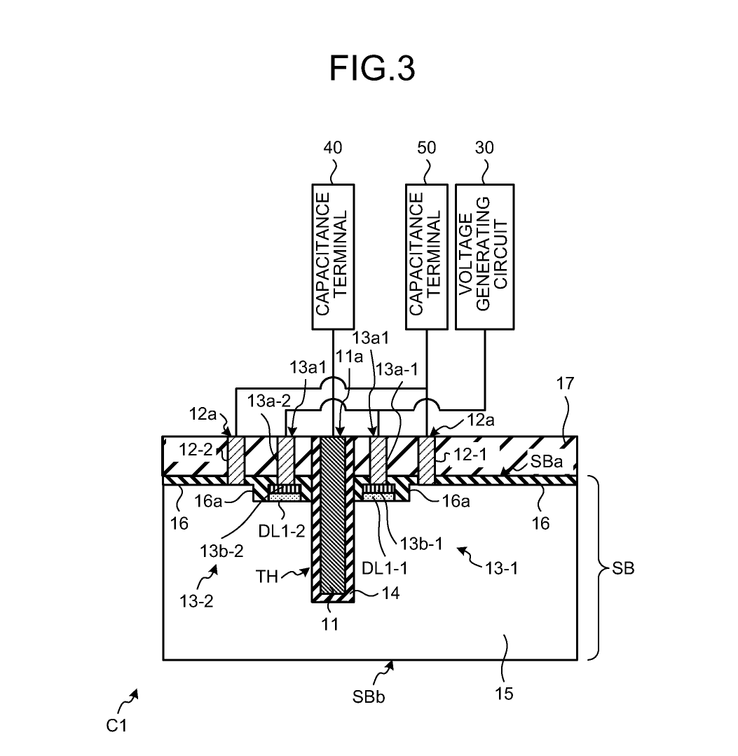

The depletion layer forming mechanism 13 can form the depletion layer 15a between the first capacitance electrode 11 and the second capacitance electrode 12 (e.g., in a region of the semiconductor layer 15 between the first capacitance electrode 11 and the second capacitance electrode 12) under the control of the control circuit CC. For example, the depletion layer forming mechanism 13 forms the depletion layer 15a between the insulating film 14 and the second capacitance electrode 12. For example, the depletion layer forming mechanism 13 has a control electrode 13a (see FIG. 3), and forms the depletion layer 15a according to a bias voltage received by the control electrode 13a from the control circuit CC. The control electrode 13a is a control electrode provided as a part of the depletion layer forming mechanism 13, for example. The depletion layer forming mechanism 13 increases or decreases the depletion layer 15a according to the bias voltage, thereby changing the capacitance value of the variable capacitance element C1, for example. The depletion layer forming mechanism 13 three-dimensionally increases or decreases the depletion layer 15a (i.e., increases or decreases the volume) according to the bias voltage so as to equivalently increase or decrease at least one of the electrode area and the inter-electrode distance between the first capacitance electrode 11 and the second capacitance electrode 12, thereby changing the capacitance value of the variable capacitance element C1.

The control circuit CC has a capacitance measuring circuit 20 and a voltage generating circuit 30.

The capacitance measuring circuit 20 measures the electric capacitance between the capacitance terminal 40 and the capacitance terminal 50, i.e., between the first capacitance electrode 11 and the second capacitance electrode 12. For example, a first measuring terminal 20a of the capacitance measuring circuit 20 is connected to the capacitance terminal 40 and the first capacitance electrode 11 via a node N2, a second measuring terminal 20b is connected to the capacitance terminal 50 and the second capacitance electrode 12 via a node N3, and an output terminal 20c is connected to the voltage generating circuit 30. For example, the capacitance measuring circuit 20 measures the electric capacitance between the first capacitance electrode 11 and the second capacitance electrode 12 via the first measuring terminal 20a and the second measuring terminal 20b, and outputs the result of the measurement to the voltage generating circuit 30 via the output terminal 20c.

The voltage generating circuit 30 receives the result of the measurement from the capacitance measuring circuit 20. The voltage generating circuit 30 applies the bias voltage to the control electrode 13a (see FIG. 3) according to the measurement result of the capacitance measuring circuit. For example, the voltage generating circuit 30 includes a generating unit 31 and a control unit 32. The generating unit 31 generates the bias voltage that is to be applied to the control electrode 13a. The control unit 32 controls the bias voltage generated in the generating unit 32 in order that the electric capacitance measured by the capacitance measuring circuit 20 becomes close to the target value. The target value is represented by the control signal CS1 externally received (e.g., from the main circuit MC).

It should be noted a reference bias (e.g., ground voltage) may be applied to the region located on the opposite side of the depletion layer forming mechanism 13 in the semiconductor layer 15. With this operation, the depletion layer forming mechanism 13 can precisely be controlled to increase or decrease the depletion layer 15a by controlling the bias voltage that is to be applied to the control electrode 13a, if the reference bias voltage is kept to be almost constant.

In the structure illustrated in FIG. 2, the increase and decrease of the depletion layer 15a can be controlled by the bias voltage input to the depletion layer forming mechanism 13 from the voltage generating circuit 30. The bias voltage output from the voltage generating circuit 30 is controlled according to the measurement result of the capacitance measuring circuit 20. With this structure, the electric capacitance between the capacitance terminal 40 and the capacitance terminal 50 is measured by the capacitance measuring circuit 20, and the bias voltage that is to be output from the voltage generating circuit 30 is adjusted in consideration of this result, whereby the depletion layer 15a is increased and decreased. Thus, the capacitance value of the variable capacitance element C1 can be controlled to be close to the target value.

This process can not only change the capacitance value of the variable capacitance element C1, but also dramatically decrease the error in the capacitance value of the variable capacitance element C1 in the initial stage caused by the variation in the production process, because of the increase and decrease of the depletion layer 15a.

The specific structure of the variable capacitance element C1 will be described with reference to FIG. 3. FIG. 3 is a view illustrating a cross-sectional structure of the variable capacitance element C1.

As illustrated in FIG. 3, the first capacitance electrode 11 is buried in a hole TH formed in a semiconductor substrate SB via the insulating film 14. For example, the hole TH penetrates an interlayer insulating film 17 and an element isolation region 16, and extends in the semiconductor substrate SB (i.e., in the semiconductor layer 15) from a front surface SBa toward a back surface SBb of the semiconductor substrate SB. The hole TH may be a cylindrical column, a rectangular column, or a groove (specifically, the hole TH may extend in the perspective direction of the sheet in FIG. 3), for example. Corresponding to this, the first capacitance electrode 11 extends in the semiconductor substrate SB from the front surface SBa of the semiconductor substrate SB toward the back surface SBb. The first capacitance electrode 11 may be a cylindrical column, a rectangular column, or a plate type (specifically, the first capacitance electrode 11 may extend in the perspective direction of the sheet in FIG. 3), for example. The insulating film 14 is formed to electrically isolate the first capacitance electrode 11 and the semiconductor layer 15.

The first capacitance electrode 11 may be made of tungsten or copper, for example. Alternatively, the first capacitance electrode 11 may be made of semiconductor having conductivity, such as polysilicon containing an impurity (e.g., boron, aluminum, etc.) of a first conductive type (e.g., p-type), or polysilicon containing an impurity (e.g., phosphor, arsenic, etc.) of a second conductive type (e.g., n-type). The insulating film 14 may be made of a material containing silicon oxide as a main component, or may be made of a material containing silicon nitride as a main component.

This structure can be formed by a process described below. After the element isolation region 16 is formed on the semiconductor substrate SB, and the interlayer insulating film 17 is formed on the semiconductor substrate SB, the hole TH is formed by etching (e.g., dry etching or wet etching). The insulating film 14 is buried in the hole TH, and is etched back in order that the insulating film 14 is selectively left on the bottom surface and the inner side face of the hole TH. Thereafter, the material that is to become the first capacitance electrode 11 is buried in the hole TH.

At least a part (i.e., the portion electrically connected to the capacitance terminal 40) of a surface 11a of the first capacitance electrode 11 on the front surface SBa of the semiconductor substrate SB is exposed. The first capacitance electrode 11 is electrically connected to the capacitance terminal 40 via the exposed region of the surface 11a.

The second capacitance electrode 12 is provided on the surface SBa of the semiconductor substrate SB so as to be separated from the first capacitance electrode 11. For example, the second capacitance electrode 12 is arranged on the position shifted from the position of the first capacitance electrode 11 along the surface SBa of the semiconductor substrate SB. For example, a second capacitance electrode 12-1 is arranged on the position shifted from the position of the first capacitance electrode 11 to the right along the surface SBa of the semiconductor substrate SB in FIG. 3. For example, a second capacitance electrode 12-2 is arranged on the position shifted from the position of the first capacitance electrode 11 to the left along the surface SBa of the semiconductor substrate SB in FIG. 3.

For example, the second capacitance electrode 12 extends through the interlayer insulating film 17 and the element isolation region 16 to be in contact with the semiconductor layer 15. The second capacitance electrode 12 may be a cylindrical column, a rectangular column, or a plate type (specifically, the second capacitance electrode 12 may extend in the perspective direction of the sheet in FIG. 3), for example. Thus, the second capacitance electrode 12 is electrically connected to the semiconductor layer 15.

The second capacitance electrode 12 may be made of tungsten or copper, for example. Alternatively, the second capacitance electrode 12 may be made of semiconductor having conductivity, such as polysilicon containing an impurity (e.g., boron, aluminum, etc.) of a first conductive type (e.g., p-type), or polysilicon containing an impurity (e.g., phosphor, arsenic, etc.) of a second conductive type (e.g., n-type).

At least a part (i.e., the portion electrically connected to the capacitance terminal 50) of a surface 12a of the second capacitance electrode 12 on the surface SBa of the semiconductor substrate SB is exposed. The second capacitance electrode 12 is electrically connected to the capacitance terminal 50 via the exposed region of the surface 12a.

The depletion layer forming mechanism 13 is arranged between the first capacitance electrode 11 and the second capacitance electrode 12 on the surface SBa of the semiconductor substrate SB in order to form the depletion layer 15a between the first capacitance electrode 11 and the second capacitance electrode 12 (e.g., in the region between the first capacitance electrode 11 and the second capacitance electrode 12 in the semiconductor layer 15). For example, a depletion layer forming mechanism 13-1 is provided between the first capacitance electrode 11 and the second capacitance electrode 12-1. For example, a depletion layer forming mechanism 13-2 is provided between the first capacitance electrode 11 and the second capacitance electrode 12-2.

Specifically, the depletion layer forming mechanism 13 has the control electrode 13a and a well region 13b. The control electrode 13a is provided between the first capacitance electrode 11 and the second capacitance electrode 12 on the surface SBa of the semiconductor substrate SB. For example, a control electrode 13a-1 is provided between the first capacitance electrode 11 and the second capacitance electrode 12-1 on the surface SBa of the semiconductor substrate SB. For example, a control electrode 13a-2 is provided between the first capacitance electrode 11 and the second capacitance electrode 12-2 on the surface SBa of the semiconductor substrate SB.

For example, the control electrode 13a extends through the interlayer insulating film 17 and the element isolation region 16 to be in contact with the well region 13b. The control electrode 13a may be a cylindrical column, a rectangular column, or a plate type (specifically, the control electrode 13a may extend in the perspective direction of the sheet in FIG. 3), for example. Thus, the control electrode 13a is electrically connected to the well region 13b.

At least a part (i.e., the portion electrically connected to the voltage generating circuit 50) of a surface 13a1 of the control electrode 13a on the surface SBa of the semiconductor substrate SB is exposed. The control electrode 13a is electrically connected to the voltage generating circuit 30 via the exposed region of the surface 13a1.

The well region 13b is electrically connected to the control electrode 13a, and forms a pn junction with the semiconductor layer 15. When the semiconductor layer 15 is made of the semiconductor containing an impurity (e.g., boron, aluminum, etc.) of a first conductive type (e.g., p-type), for example, the well region 13b may be made of semiconductor containing an impurity (e.g., phosphor, arsenic, etc.) of a second conductive type (e.g., n-type) with a concentration higher than the concentration of the first conductive impurity in the semiconductor layer 15. Alternatively, when the semiconductor layer 15 is made of the semiconductor containing an impurity (e.g., phosphor, arsenic, etc.) of a second conductive type (e.g., n-type), for example, the well region 13b may be made of semiconductor containing an impurity (e.g., boron, aluminum, etc.) of a first conductive type (e.g., p-type) with a concentration higher than the concentration of the second conductive impurity in the semiconductor layer 15.

The control electrode 13a may be made of tungsten or copper, for example. Alternatively, the control electrode 13a may be made of semiconductor having conductivity same as the conductive type of the well region 13b. When the well region 13b is made of polysilicon containing the impurity of the first conductive type, for example, the control electrode 13a may be made of polysilicon containing the impurity of the first conductive type. When the well region 13b is made of polysilicon containing the impurity of the second conductive type, for example, the control electrode 13a may be made of polysilicon containing the impurity of the second conductive type.

The well region 13b may be arranged to enclose the first capacitance electrode 11, for example. The voltage generating circuit 30 is electrically connected to the well region 13b via the control electrode 13a. Thus, a reverse bias voltage can be applied to the interface between the well region 13b and the semiconductor layer 15, i.e., to the pn junction interface, whereby a depletion layer DL1 can be formed by the pn junction. When a positive voltage is applied to the control electrode 13a in case where the well region 13b is made of the semiconductor containing the impurity of the second conductive type (e.g., n-type), and the semiconductor layer 15 is made of the semiconductor containing the impurity of the first conductive type (e.g., p-type), a reverse bias voltage is applied to the pn junction interface. When a negative voltage is applied to the control electrode 13a in case where the well region 13b is made of the semiconductor containing the impurity of the first conductive type (e.g., p-type), and the semiconductor layer 15 is made of the semiconductor containing the impurity of the second conductive type (e.g., n-type), the reverse bias voltage is applied to the pn junction interface.

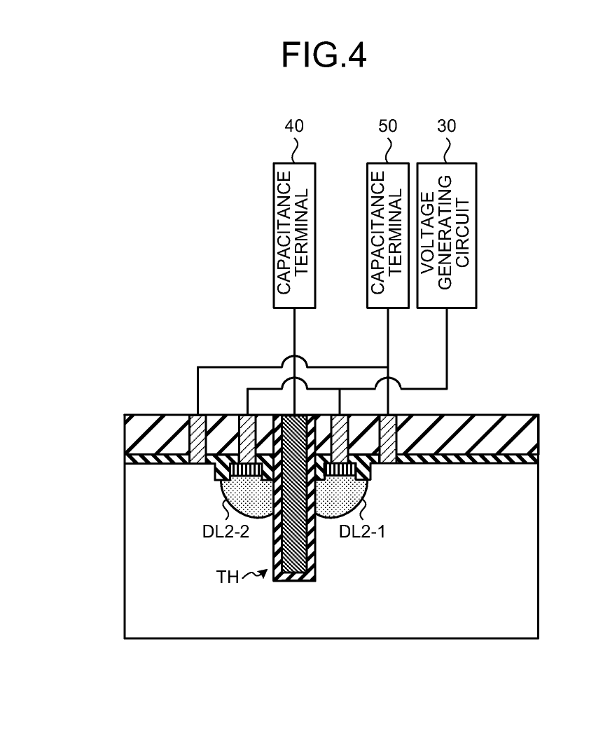

The depletion layer DL1-1 can be formed between the well region 13b-1 and the semiconductor layer 15 by applying the reverse bias voltage with respect to the pn junction interface to the well region 13b-1 via the control electrode 13a-1 from the voltage generating circuit 30. In this case, when the value of the bias voltage in the reverse direction increases from the state illustrated in FIG. 3, the depletion layer DL2-1 can be extended in the direction along the hole TH as illustrated in FIG. 4. When the value of the reverse bias voltage decreases from the state illustrated in FIG. 4, the depletion layer DL1-1 can be decreased in the direction along the hole TH as illustrated in FIG. 3. Specifically, the depletion layer forming mechanism 13-1 forms the depletion layers DL1-1 and DL2-1 to be extended or reduced in the direction along the hole TH.

The depletion layer DL1-2 can be formed between the well region 13b-2 and the semiconductor layer 15 by applying the bias voltage in the reverse direction with respect to the pn junction interface to the well region 13b-2 via the control electrode 13a-2 from the voltage generating circuit 30. In this case, when the value of the bias voltage in the reverse direction increases from the state illustrated in FIG. 3, the depletion layer DL2-2 can be extended in the direction along the hole TH as illustrated in FIG. 4. When the value of the reverse bias voltage decreases from the state illustrated in FIG. 4, the depletion layer DL1-2 can be decreased in the direction along the hole TH as illustrated in FIG. 3. Specifically, the depletion layer forming mechanism 13-2 forms the depletion layers DL1-2 and DL2-2 to be extended or reduced in the direction along the hole TH.

The element isolation region 16 may have an STI (Shallow Trench Isolation) structure 16a around the well region 13b in order to electrically isolate the well region 13b from the surrounding region.

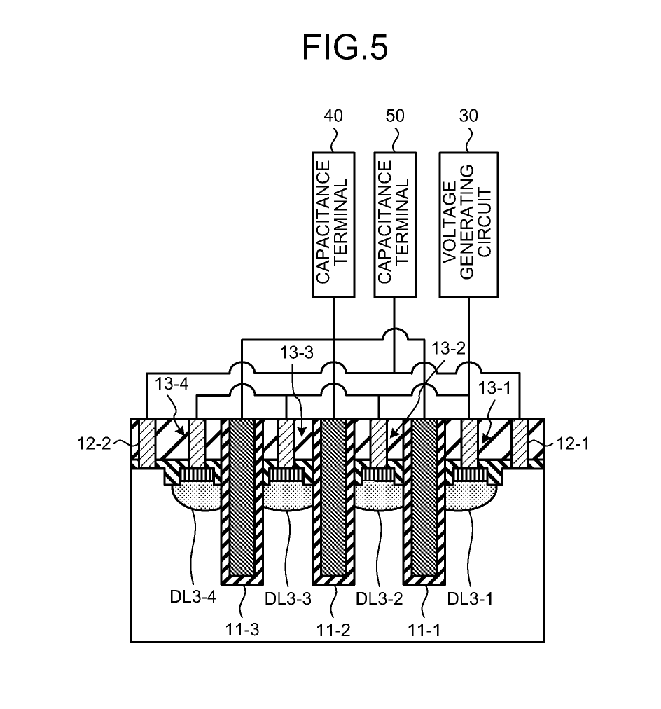

As described above, the control electrode 13a and the well region 13b function as the depletion layer forming mechanism 13 (see FIG. 2) in the structure illustrated in FIG. 3. The depletion layers DL1 and DL2 equivalently work as the insulator. Therefore, the electric capacitance between the capacitance terminal 40 and the capacitance terminal 50 can be changed by increasing and decreasing the depletion layers DL1 and DL2 around the first capacitance electrode 11, whereby the variable capacitance element C1 can be realized. In the present embodiment, the depletion layers DL1 and DL2 are formed independent of the capacitance terminal 40 and the capacitance terminal 50 by the depletion layer forming mechanism 13. Therefore, when the arrangement pitch between plural first capacitance electrodes 11-1 to 11-3 is set to be small as illustrated in FIG. 5, for example, depletion layers DL3-1 to DL3-4 are difficult to combine in the lateral direction, with the result that the capacitance can easily be increased.

Suppose a case where the variable capacitance element C1100 illustrated in FIG. 11 is used as the variable capacitance element in the semiconductor device 100. In the variable capacitance element C1100 illustrated in FIG. 11, the capacitance value is mainly determined by the area of the pn junction. Therefore, the electrode area has to be increased in order to increase the capacitance value. When the electrode area increases, the size of the variable capacitance element C1100 along the surface 1115p1 might be large. With this, the chip area of the semiconductor device 100 including the variable capacitance element C1100 might be increased, which makes it difficult to realize the compact mounting of the semiconductor device 100.

On the other hand, in the first embodiment, the first capacitance electrode 11 is buried in the hole TH, formed on the semiconductor substrate SB, via the insulating film 14 in the variable capacitance element C1 of the semiconductor device 100. The second capacitance electrode 12 is arranged on the surface SBa of the semiconductor substrate SB so as to be separated from the first capacitance electrode 11. The depletion layer forming mechanism 13 has the control electrode 13a, and forms the depletion layer between the first capacitance electrode 11 and the second capacitance electrode 12. With this structure, the electrode area can be secured in the depth direction of the semiconductor substrate SB in the variable capacitance element C1, whereby the capacitance value between two capacitance electrodes (the first capacitance electrode 11 and the second capacitance electrode 12), and the size between two capacitance electrodes can be reduced. As a result, the capacitance value of the variable capacitance element C1 can significantly be increased, while preventing the increase in the size of the variable capacitance element C1 along the surface SBa.

Accordingly, the semiconductor device 100 including the LC resonance circuit LC1 can be made compact, and the wide control range of the resonance point of the LC resonance circuit can be secured.

Suppose a case where the variable capacitance element C1200 illustrated in FIG. 12 is used as the variable capacitance element in the semiconductor device 100. In the variable capacitance element C1200 illustrated in FIG. 12, the capacitance value is mainly determined by the area of the pn junction. Therefore, the depth of each trench has to be deep, or the pitch between the trenches has to be reduced in order to increase the capacitance value. The variable capacitance element C1200 illustrated in FIG. 12 has the limitation in the precision of the ion implantation. Therefore, it is difficult to deepen each trench in consideration of a process. When the pitch between the adjacent trenches is set to be small in the variable capacitance element C1200 in FIG. 12, the depletion layer might be combined between the adjacent trenches, and hence, the effective electrode area might be decreased. Therefore, slight increase in the capacitance value is only realized in the variable capacitance element illustrated in FIG. 12. Thus, it is difficult to increase the capacitance in the variable capacitance element C1200 in FIG. 12.

On the other hand, in the first embodiment, the first capacitance electrode 11 is buried in the hole TH, formed on the semiconductor substrate SB, via the insulating film 14 in the variable capacitance element C1 of the semiconductor device 100. The second capacitance electrode 12 is arranged on the surface SBa of the semiconductor substrate SB so as to be separated from the first capacitance electrode 11. The depletion layer forming mechanism 13 has the control electrode 13a, and forms the depletion layer between the first capacitance electrode 11 and the second capacitance electrode 12. With this structure, when the plural first capacitance electrodes 11-1 to 11-3 are arranged, and the arrangement pitch among the plural first capacitance electrodes 11-1 to 11-3 is set to be small as illustrated in FIG. 5, in order to increase the electric capacitance, depletion layers DL3-1 to DL3-4 are difficult to combine in the lateral direction, with the result that the capacitance can easily be increased. Specifically, even when plural first capacitance electrodes 11-1 to 11-3 and depletion layer forming mechanisms 13-1 to 13-4 are arranged with a small pitch, the capacitance value between two capacitance electrodes (the first capacitance electrode 11 and the second capacitance electrode 12) can be increased for each pair of each of the first capacitance electrodes 11-1 to 11-3 and each of the depletion layer forming mechanisms 13-1 to 13-4. In other words, when the plural first capacitance electrodes 11-1 to 11-3 and depletion layer forming mechanisms 13-1 to 13-4 are arranged, the capacitance value between two capacitance electrodes can be increased, and the size between two capacitance electrodes can be decreased, for each pair of each of the first capacitance electrodes 11-1 to 11-3 and each of the second capacitance electrodes 12-1 and 12-2.

Accordingly, from this viewpoint, the semiconductor device 100 including the LC resonance circuit LC1 can be made compact, and the wide control range of the resonance point of the LC resonance circuit can be secured.

In the variable capacitance element C1100 illustrated in FIG. 11, it is difficult to finely adjust the capacitance value analogically, since the terminal for applying the reverse bias voltage to the pn junction and the terminal for extracting the capacitance value are shared in the semiconductor layer 1115.

In the variable capacitance element C1200 illustrated in FIG. 12, it is difficult to finely adjust the capacitance value analogically, since the terminal for applying the reverse bias voltage to the pn junction and the terminal for extracting the capacitance value are shared in the semiconductor layer 1215.

On the other hand, in the first embodiment, the first capacitance electrode 11 is buried in the hole TH, formed on the semiconductor substrate SB, via the insulating film 14 in the variable capacitance element C1 of the semiconductor device 100. The second capacitance electrode 12 is arranged on the surface SBa of the semiconductor substrate SB so as to be separated from the first capacitance electrode 11. The depletion layer forming mechanism 13 has the control electrode 13a, and forms the depletion layer between the first capacitance electrode 11 and the second capacitance electrode 12. With this structure, the depletion layer forming mechanism 13 can be worked via the control electrode 13a as being independent of the capacitance terminal 40 connected to the first capacitance electrode 11 and the capacitance terminal 50 connected to the second capacitance electrode 12, whereby the depletion layer can be formed between the first capacitance electrode 11 and the second capacitance electrode 12. Specifically, the electric capacitance between the first capacitance electrode 11 and the second capacitance electrode 12 can be controlled without being affected by the extraction of the capacitance value, whereby the electric capacitance between the first capacitance electrode 11 and the second capacitance electrode 12 can finely be adjusted analogically.

In the first embodiment, in the variable capacitance element C1 of the semiconductor device 100, the hole TH extends in the semiconductor substrate SB from the front surface SBa toward the back surface SBb of the semiconductor substrate SB. At least a part of the first capacitance electrode 11 on the surface SBa of the semiconductor substrate SB is exposed. With this structure, the first capacitance electrode 11 can easily be connected electrically to the first capacitance terminal 40, whereby the electric capacitance between the first capacitance electrode 11 and the second capacitance electrode 12 can be extracted and supplied to the outside (e.g., the main circuit MC).

In the first embodiment, the second capacitance electrode 12 is arranged on the surface SBa of the semiconductor substrate SB in the variable capacitance element C1 of the semiconductor device 100. The control electrode 13a is arranged on the surface SBa of the semiconductor substrate SB. With this structure, the control electrode 13a is arranged between the first capacitance electrode 11 and the second capacitance electrode 12 in the direction along the surface SBa of the semiconductor substrate SB. Accordingly, the second capacitance electrode 12 can be arranged so as to be separated from the first capacitance electrode 11, and the control electrode 13a can be arranged on the position suitable for forming the depletion layer between the first capacitance electrode 11 and the second capacitance electrode 12.

In the first embodiment, the well region 13b of the depletion layer forming mechanism 13 is electrically connected to the control electrode 13a, and the pn junction is formed between the well region 13b and the semiconductor layer 15 in the variable capacitance element C1 of the semiconductor device 100. Thus, the bias voltage in the direction reverse to the pn junction can be applied to the well region 13b via the control electrode 13a.

In the first embodiment, the semiconductor layer 15 contains the impurity of the first conductive type in the variable capacitance element C1 of the semiconductor device 100. The well region 13b contains the impurity of the second conductive type that is reverse to the first conductive type. Thus, the well region 13b can be configured to form the pn junction with the semiconductor layer 15.

In the first embodiment, the capacitance measuring circuit 20 measures the electric capacitance between the first capacitance electrode 11 and the second capacitance electrode 12, and feeds the measurement result to the voltage generating circuit 30 in the control circuit CC of the semiconductor device 100. The voltage generating circuit 30 applies the bias voltage to the control electrode 13a according to the measurement result of the capacitance measuring circuit 20. Thus, when the electric capacitance of the variable capacitance element C1 has a production variation, the electric capacitance of the variable capacitance element C1 can be corrected to be close to the target value (for example, corrected to agree with the target value), whereby the influence of the production variation of the electric capacitance, which should be fed to the outside (e.g., the main circuit MC), of the variable capacitance element C1 can be reduced. When the electric capacitance of the variable capacitance element C1 dynamically changes due to a charge, the electric capacitance of the variable capacitance element C1 can be corrected to be close to the target value (for example, corrected to agree with the target value), whereby the change in the electric capacitance, which should be fed to the outside (e.g., the main circuit MC), of the variable capacitance element C1 caused by the charge can be corrected.

In the first embodiment, in the control circuit CC of the semiconductor device 100, the generating unit 31 of the voltage generating circuit 30 generates the bias voltage that should be applied to the control electrode 13a. The control unit 32 controls the bias voltage, generated by the generating unit 31, in order that the electric capacitance measured by the capacitance measuring circuit 20 becomes close to the target value. With this structure, the electric capacitance of the variable capacitance element C1 can be corrected to be close to (for example, to agree with) the target value.

In the first embodiment, in the variable capacitance element C1 of the semiconductor device 100, the depletion layer forming mechanism 13 forms the depletion layers DL1 and DL2 that can extend and reduce in the direction along the hole TH. Specifically, the depletion layer forming mechanism 13 changes the electric capacitance between the first capacitance electrode 11 and the second capacitance electrode 12 by extending and reducing the depletion layers DL1 and DL2 in the direction along the hole TH. With this, the electric capacitance between the first capacitance electrode 11 and the second capacitance electrode 12 can three-dimensionally be changed. For example, the effective electrode area and the distance between the first capacitance electrode 11 and the second capacitance electrode 12 can both be changed, whereby the wide control range of the electric capacitance between the first capacitance electrode 11 and the second capacitance electrode 12 can easily be secured.

In the first embodiment, in the semiconductor device 100, the control circuit CC controls the depletion layer forming mechanism 13 according to the control signal CS1. The depletion layer forming mechanism 13 changes the resonance frequency of the variable capacitance element C1 and the inductance element L1 by extending and reducing the depletion layers DL1 and DL2 along the hole TH under the control of the control circuit CC. Thus, the LC resonance circuit LC1 including the variable capacitance element C1, the inductance element L1, and the control circuit CC can provide the resonance frequency according to the control signal CS1 from the main circuit MC to the main circuit MC.

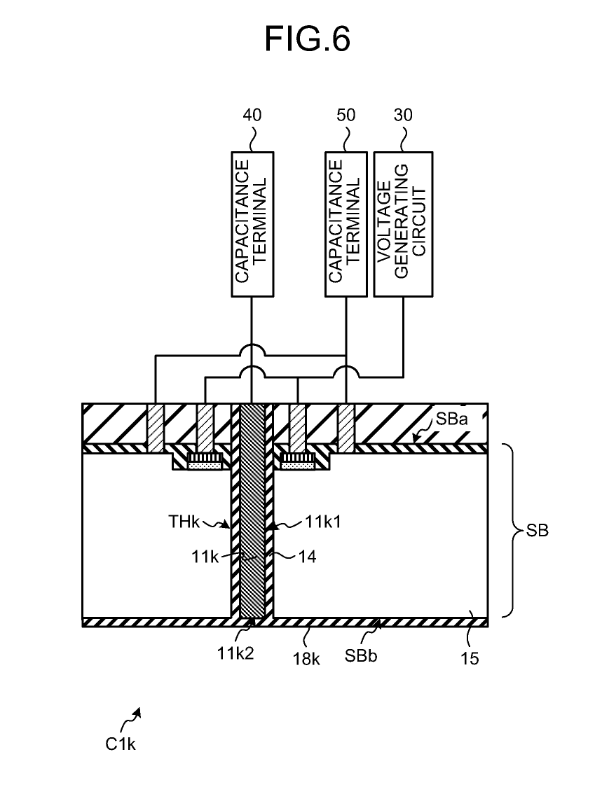

It should be noted that, in a variable capacitance element C1k, the first capacitance electrode 11k may be a through-hole via as illustrated in FIG. 6. Specifically, the hole TH penetrates the interlayer insulating film 17 and the element isolation region 16 to extend through the semiconductor substrate SB from the front surface SBa to the back surface SBb of the semiconductor substrate SB. With this, a first capacitance electrode 11k penetrates to extend through the semiconductor substrate SB from the front surface SBa to the back surface SBb of the semiconductor substrate SB. In this case, the insulating film 14 covers a side face 11k1 of the first capacitance electrode 11k so as to electrically insulate the first capacitance electrode 11k and the semiconductor layer 15. An insulating film 18k may be provided to cover a face 11k2, on the back surface SBb of the semiconductor substrate SB, of the first capacitance electrode 11k. The insulating film 18k may also cover the back surface SBb of the semiconductor substrate SB. Thus, the first capacitance electrode 11k and the back surface SBb of the semiconductor substrate SB can be protected.

Alternatively, when plural first capacitance electrodes are provided as illustrated in FIG. 5, plural variable capacitance element groups, each having a different number of first capacitance electrodes, are provided. The capacitance is digitally changed by electrically switching the combination thereof, and the capacitance is analogically changed by the bias voltage, whereby the variable capacitance element C1 can be utilized as the wide-ranging analog variable capacitance element.

### Second Embodiment

Next, a semiconductor device 200 according to a second embodiment will be described. The part different from the first embodiment will mainly be described below.

The first embodiment illustratively describes the structure for forming the depletion layer through the application of the reverse bias voltage to the pn junction. On the other hand, the second embodiment illustratively describes a structure for forming the depletion layer by utilizing a MOS structure.

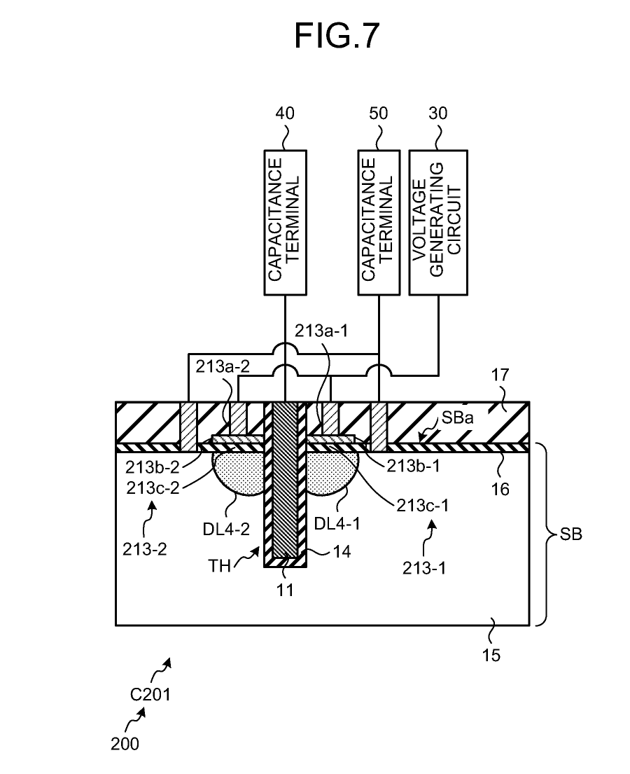

The semiconductor device 200 has a variable capacitance element C201 illustrated in FIG. 7, for example, instead of the variable capacitance element C1 (see FIG. 3). The variable capacitance element C201 has a depletion layer forming mechanism 213 instead of the depletion layer forming mechanism 13 (see FIG. 3). The depletion layer forming mechanism 213 forms the depletion layer by utilizing the MOS structure.

Specifically, the depletion forming mechanism 213 includes control electrodes 213a and 213b, and a gate insulating film 213c. The control electrode 213a penetrates the interlayer insulating film 17 to extend to be in contact with the control electrode 213b. Thus, the control electrode 213a is electrically connected to the control electrode 213b.

The control electrode 213b is arranged on the front surface SBa of the semiconductor substrate SB. The control electrode 213b is electrically connected to the control electrode 213a, and is provided to cover the gate insulating film 213c. For example, the control electrode 213b has a width larger than the control electrode 213a in the direction along the front surface SBa of the semiconductor substrate SB. Thus, the control electrode 213a is easy to be electrically connected to the control electrode 213b.

The control electrode 213b may be made of tungsten or copper, for example. Alternatively, the control electrode 213b may be made of semiconductor having conductivity, such as polysilicon containing an impurity of a first conductive type (e.g., p-type), or polysilicon containing an impurity of a second conductive type (e.g., n-type).

The gate insulating film 213c is arranged on the front surface SBa of the semiconductor substrate SB. The gate insulating film 213c is provided to be sandwiched between the control electrode 213b and the semiconductor layer 15. The gate insulating film 213c covers the semiconductor layer 15. The gate insulating film 213c may be made of a material containing silicon oxide as a main component, or may be made of a material containing silicon nitride as a main component. The gate insulating film 213c may be continuous with the element isolation region 16. In this case, the gate insulating film 213c may simultaneously be formed during the process (e.g., a thermal oxidation process) of forming the element isolation region 16.

The voltage generating circuit 30 is electrically connected to the control electrode 213b via the control electrode 213a. With this structure, a positive bias voltage can be applied to the interface between the control electrode 213b and the semiconductor layer 15, i.e., to the MOS junction interface, whereby a depletion layer DL4 due to the MOS structure can be formed. In this case, it is preferable that the bias voltage is adjusted in order not to form an inversion layer in the semiconductor layer 15.

For example, the depletion layer DL4-1 can be formed near the gate insulating film 213c-1 in the semiconductor layer 15 by applying the positive bias voltage to the control electrode 213b-1 from the voltage generating circuit 30 via the control electrode 213a-1. When the positive bias voltage increases, the depletion layer DL4-1 can be extended in the direction along the hole TH. When the positive bias voltage decreases, the depletion layer DL4-1 can be reduced in the direction along the hole TH. Specifically, the depletion layer forming mechanism 213-1 forms the depletion layer DL4-1 so as to be extended and reduced along the hole TH.

For example, the depletion layer DL4-2 can be formed near the gate insulating film 213c-2 in the semiconductor layer 15 by applying the positive bias voltage to the control electrode 213b-2 from the voltage generating circuit 30 via the control electrode 213a-2. When the positive bias voltage increases, the depletion layer DL4-2 can be extended in the direction along the hole TH. When the positive bias voltage decreases, the depletion layer DL4-2 can be reduced in the direction along the hole TH. Specifically, the depletion layer forming mechanism 213-2 forms the depletion layer DL4-2 so as to be extended and reduced along the hole TH.

As described above, in the second embodiment, the depletion layer forming mechanism 213 includes the control electrode 213b, and the gate insulating film 213c sandwiched between the control electrode 213b and the semiconductor layer 15 in the variable capacitance element C201 of the semiconductor device 200. Accordingly, the depletion layer forming mechanism 213 can form the depletion layer by utilizing the MOS structure.

In the variable capacitance element C201 of the semiconductor device 200 according to the second embodiment, the gate insulating film 213c is formed on the front surface SBa of the semiconductor substrate SB, for example. The control electrode 213b is arranged on the front surface SBa of the semiconductor substrate SB to cover the gate insulating film 213c, for example. Thus, the MOS structure can be realized on the front surface SBa of the semiconductor substrate SB.

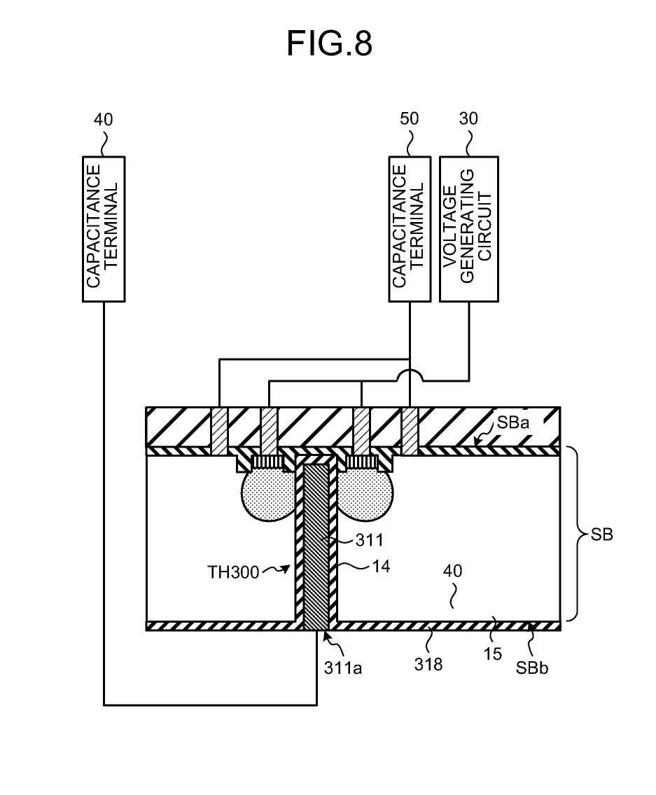

It should be noted that, in the first and second embodiments, the hole into which the first capacitance electrode should be buried may extend in the semiconductor substrate from the back surface toward the front surface of the semiconductor substrate. For example, in the first embodiment, as illustrated in FIG. 8, a hole TH300 into which a first capacitance electrode 311 should be buried may extend in the semiconductor substrate SB from the back surface SBb toward the front surface SBa of the semiconductor substrate SB. At least a part of a surface 311a of the first capacitance electrode 311 on the back surface SBb of the semiconductor substrate SB is exposed. Accordingly, the first capacitance electrode 311 can easily be connected to the capacitance terminal 40 via the exposed region of the surface 311a.

As illustrated in FIG. 8, the first capacitance electrode 311 may be a through-hole via. Specifically, the hole TH300 penetrates the semiconductor substrate SB from the back surface SBb to the front surface SBa of the semiconductor substrate SB. According to this structure, the first capacitance electrode 311 penetrates the semiconductor substrate SB to extend from the back surface SBb to the front surface SBa of the semiconductor substrate SB. In this case, an insulating film 318 may be formed to cover the back surface SBb of the semiconductor substrate SB. Thus, the back surface SBb of the semiconductor substrate SB can be protected.

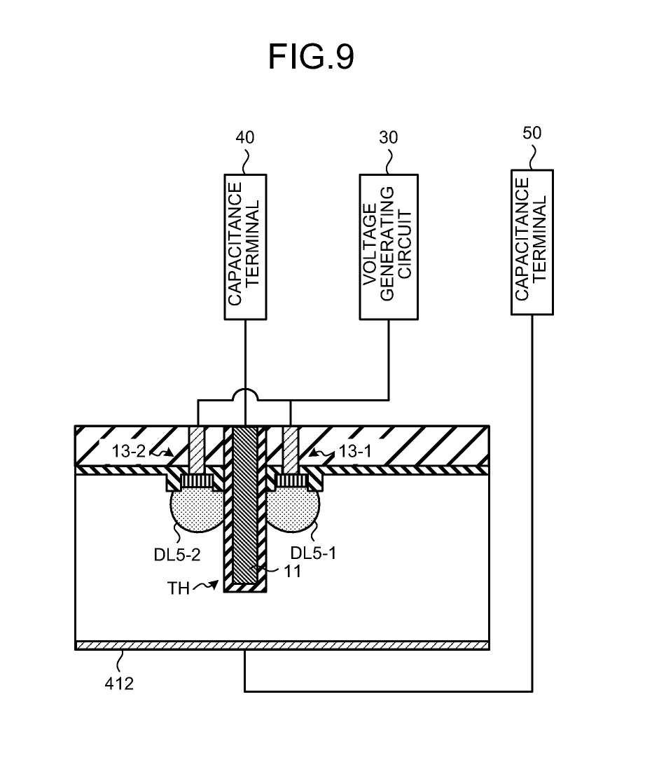

Alternatively, in the first and second embodiments, the second capacitance electrode may be provided on the back surface of the semiconductor substrate. For example, in the first embodiment, as illustrated in FIG. 9, a second capacitance electrode 412 is formed to cover at least a region corresponding to the first capacitance electrode 11 and the depletion layer forming mechanisms 13-1 and 13-2 on the back surface SBb of the semiconductor substrate SB. For example, the second capacitance electrode 412 may cover all over the back surface SBb of the semiconductor substrate SB as illustrated in FIG. 9. Even in this case, the depletion layer forming mechanism 13 can change the electric capacitance between the first capacitance electrode 11 and the second capacitance electrode 412 by extending and reducing depletion layers DL5-1 and DL5-2 in the direction along the hole TH.

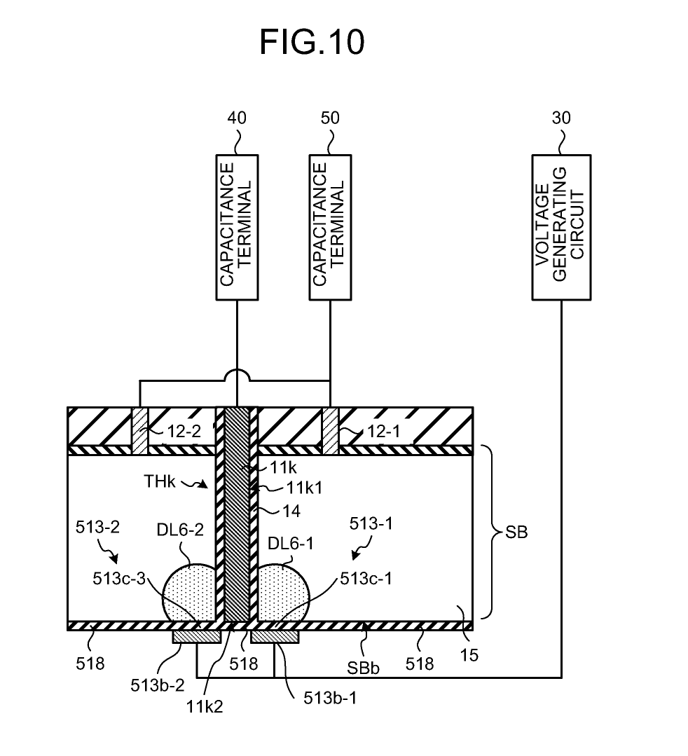

Alternatively, in the first and second embodiments, the depletion layer forming mechanism may be formed on the back surface of the semiconductor substrate. For example, in the combination of modification of the first embodiment and the second embodiment, a depletion layer forming mechanism 513 includes a control electrode 513b and a gate insulating film 513c as illustrated in FIG. 10. The control electrode 513b is provided on the back surface SBb of the semiconductor substrate SB. The capacitance terminal 50 is electrically connected to the control electrode 513b, and the control electrode 513b is formed to cover the gate insulating film 513c. The gate insulating film 513c is arranged on the back surface SBb of the semiconductor substrate SB. The gate insulating film 513c is formed to be sandwiched between the control electrode 513b and the semiconductor layer 15. The gate insulating film 513c covers the semiconductor layer 15. Even in this case, the depletion layer forming mechanism 513 can change the electric capacitance between the first capacitance electrode 11k and the second capacitance electrodes 12-1 and 12-2 by extending and reducing depletion layers DL6-1 and DL6-2 in the direction along the hole TH.

In this case, the insulating film 14 covers the side face 11k1 of the first capacitance electrode 11 in order to electrically insulate the first capacitance electrode 11k and the semiconductor layer 15. However, an insulating film 518 may be provided to cover a face 11k2 of the first capacitance electrode 11k on the back surface SBb of the semiconductor substrate SB. The insulating film 518 may also cover the back surface SBb of the semiconductor substrate SB. Thus, the first capacitance electrode 11k and the back surface SBb of the semiconductor substrate SB can be protected.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first capacitance electrode buried in a hole via an insulating film, the hole being formed in a semiconductor substrate;
a second capacitance electrode formed on a front surface side or on a back surface side of the semiconductor substrate so as to be separated from the first capacitance electrode; and
a depletion layer forming mechanism that includes a control electrode, and forms a depletion layer between the first capacitance electrode and the second capacitance electrode.

2. The semiconductor device according to claim 1, wherein
the hole extends through the semiconductor substrate from the front surface toward the back surface of the semiconductor substrate, and
at least a part of the first capacitance electrode on the front surface side of the semiconductor substrate is exposed.

3. The semiconductor device according to claim 2, wherein
the hole penetrates the semiconductor substrate from the front surface to the back surface, and
the first capacitance electrode is a through-hole via.

4. The semiconductor device according to claim 2, wherein
the second capacitance electrode is provided on the front surface side of the semiconductor substrate, and
the control electrode is arranged on the front surface side of the semiconductor substrate.

5. The semiconductor device according to claim 2, wherein
the second capacitance electrode is provided on the back surface side of the semiconductor substrate, and
the control electrode is arranged on the front surface side of the semiconductor substrate.

6. The semiconductor device according to claim 2, wherein
the second capacitance electrode is provided on the front surface side of the semiconductor substrate, and
the control electrode is arranged on the back surface side of the semiconductor substrate.

7. The semiconductor device according to claim 1, wherein
the hole extends through the semiconductor substrate from the back surface toward the front surface of the semiconductor substrate, and
at least a part of the first capacitance electrode on the back surface side of the semiconductor substrate is exposed.

8. The semiconductor device according to claim 7, wherein
the hole penetrates the semiconductor substrate from the back surface to the front surface, and
the first capacitance electrode is a through-hole via.

9. The semiconductor device according to claim 7, wherein
the second capacitance electrode is provided on the front surface side of the semiconductor substrate, and
the control electrode is arranged on the front surface side of the semiconductor substrate.

10. The semiconductor device according to claim 1, wherein
the semiconductor substrate includes a semiconductor layer, and
the depletion layer forming mechanism includes:
the control electrode; and
a well region connected to the control electrode to form a pn junction with the semiconductor layer.

11. The semiconductor device according to claim 10, wherein
the semiconductor layer contains an impurity of a first conductive type, and
the well region contains an impurity of a second conductive type that is reverse to the first conductive type.

12. The semiconductor device according to claim 1, wherein
the semiconductor substrate includes a semiconductor layer, and
the depletion layer forming mechanism includes:
the control electrode; and
a gate insulating film sandwiched between the control electrode and the semiconductor layer.

13. The semiconductor device according to claim 12, wherein
the control electrode is arranged on the front surface side of the semiconductor substrate.

14. The semiconductor device according to claim 13, wherein
the control electrode includes
a first control electrode, and
a second control electrode which has a width larger than the first control electrode and on which the first control electrode is arranged.

15. The semiconductor device according to claim 12, wherein
the control electrode is arranged on the back surface side of the semiconductor substrate.

16. The semiconductor device according to claim 1, further comprising:
a capacitance measuring circuit configured to measure an electric capacitance between the first capacitance electrode and the second capacitance electrode; and
a voltage generating circuit configured to apply a bias voltage to the control electrode according to the measurement result of the capacitance measuring circuit.

17. The semiconductor device according to claim 16, wherein
the voltage generating circuit includes:
a generating unit that generates the bias voltage; and
a control unit that controls the bias voltage, generated from the generating unit, in order that the electric capacitance measured by the capacitance measuring circuit becomes close to a target value.

18. The semiconductor device according to claim 1, wherein
the depletion layer forming mechanism forms the depletion layer such that the depletion layer is extended and reduced in a direction along the hole.

19. The semiconductor device according to claim 18, wherein
the depletion layer forming mechanism changes the electric capacitance between the first capacitance electrode and the second capacitance electrode by extending and reducing the depletion layer in the direction along the hole.

20. The semiconductor device according to claim 19, further comprising:
an inductance element connected to either one of the first capacitance electrode and the second capacitance electrode, wherein
the first capacitance electrode, the second capacitance electrode, and the depletion layer forming mechanism function as a variable capacitance element, and
the depletion layer forming mechanism changes a resonance frequency of the variable capacitance element and the inductance element by extending and reducing the depletion layer in the direction along the hole.
